(19) United States
(12) Patent Application Publication
(10) Pub. No.: US 2014/0244189 A1
(43) Pub. Date: Aug. 28, 2014

(54) System For Achieving Real-Time Monitoring and State Estimation in Power Distribution Networks

(71) Applicant: BIGWOOD TECHNOLOGY, INC., Ithaca, NY (US)

(72) Inventors: Hsiao-Dong Chiang, Ithaca, NY (US); Gilburt Chiang, Ithaca, NY (US)

(73) Assignee: BIGWOOD TECHNOLOGY, INC., Ithaca, NY (US)

(21) Appl. No.: 13/778,974

(22) Filed: Feb. 27, 2013

(51) Int. Cl. G01R 31/40

(52) U.S. Cl. CPC G01R 31/40
USPC 702/61

(57) ABSTRACT

A method of placing PMUs for distribution networks having a plurality of nodes, the network comprising: a feeder line attached to a source at a source node and at least one node with a lateral branching from the node on the feeder line, the method comprising the steps of: placing a VPMU and CPMU directly after the source node; locating a next node downstream along the feeder line; and for the located next node, determining a type of node located, a type of line between the source node and the located next node and whether the located next node is an end node of the feeder line; wherein if the located next node is branching node, placing a CPMU on all laterals between the branching node and an end of the lateral; determining if any of the located next nodes are attached to a dispersed generator and placing a CPMU.

### FIELD OF INVENTION

The present invention pertains to real-time monitoring of large-scale, unbalanced, power-distribution networks and more particularly, to a low-cost system for achieving real-time state estimation in power distribution networks.

### BACKGROUND OF THE INVENTION

In modern energy management systems, the state estimation (SE) program has been successfully implemented for several decades. The SE program processes a set of measurement data and produces an estimate of the system state (i.e. bus voltage magnitudes and angles). The SE program is based on the mathematical relationship between the system state variables and a set of measurement data, which can be real and reactive power measurements on current and voltage measurements. The estimated state vector obtained from the SE program is used in energy management systems for advanced applications such as power system security monitoring, power system security assessment, power system enhancement control, power system preventive control, and power system optimization.

The anticipated integration of smart grid technologies in the distribution networks will lead to its modernization and its high complexity. It is expected that dispersed generators will proliferate in distribution networks; causing bi-directional power flows in the network. It is also expected that various types of storage devices along with plug-in hybrid electric vehicles (PHEVs) will increase in distribution networks, creating changes in load profiles. These trends will make the task of real-time monitoring and control of power distribution networks rather challenging. This task requires a powerful SE function in the distribution (energy) management systems (DMSs). The various methods developed for the SE function in transmission systems however cannot be carried over to the development of a SE function in distribution systems. The main difficulties come from the following distinguished features of distribution networks from the transmission networks: (i) radial (i.e. tree-like network topology), or weakly-meshed network topology, (ii) large R/X ratio for cables, (iii) small number of real-time measurements (mostly current measurements instead of power measurements), (iv) unbalancing loading, and (v) unsymmetrical network structure. We note that an electrical, power-distribution network is considered unbalanced if it has unequal loads, regardless of whether the system is one-phase, two-phase or even three-phase.

A majority of state estimators proposed in the prior art were developed based on simplified models and assumptions such as balanced three-phase, positive sequence, and single phase equivalents. These state estimators produce significant biases in the state estimation results of three-phase unbalanced distribution networks. There are currently a few state estimators which were developed for three-phase unbalanced distribution networks. These three-phase state estimators mostly adopt a weighted-least-square (WLS) formulation of the state estimation problems, which belong to nonlinear constrained optimization problems and apply an iterative solution algorithm to solve the WLS formulation. Several issues can arise from this WLS formulation such as the issue of non-convergence and the issue of speed. Regardless of whether convergence occurs, iterative techniques can be quite time-consuming. In many cases, such as in online, so-called “real-time” control environments, or when power restoration is needed, the time needed to obtain a solution is simply unacceptable.

Phasor Measurement Units (PMU) technology can improve the capability of system operators to monitor the real-time condition of power systems. Of the applications in which PMUs can be deployed, state estimation can be significantly improved in terms of higher estimation accuracy, redundancy levels, and bad data detection. Since direct measurement of bus voltage phasors is available with PMUs, the state estimation problem becomes linear as long as a sufficient number of PMUs are optimally placed in the power network to provide full network monitoring. However, this option is still expensive and far from becoming a reality for large-scale power systems.

### SUMMARY

This application discloses direct methods for real-time state estimation of general (radial or meshed), unbalanced distribution networks using specialized measurement devices (current phasor measurement units, CPMUs). Also disclosed are methods for placing CPMUs for achieving real-time state estimation. These methods are practical and are capable of coping with a great number of nodes, branches and laterals; multiphase, grounded or ungrounded loads; dispersed generating resources including renewable energies, multiphase shunt elements and transformers of any connections in general, large-scale, unbalanced distribution systems.

Also disclosed is a direct, closed-loop method for correcting pseudo-measurement in an unbalanced, power-distribution network having a great number of nodes, branches and laterals, as well as multiphase loads. The network can be a radial structure or meshed structure.

The direct methods for real-time state estimation and methods for placing CPMUs for achieving real-time state estimation developed for large-scale, unbalanced distribution systems can be applied to many applications in real-time analysis and control to cope with: a great number of nodes/branches/laterals; both radial and meshed network structure; multiphase, grounded or ungrounded loads; dispersed generator resources; multiphase shunt elements; and transformers of any connections.

In addition, this invention develops direct and robust methods to estimate a subset of the state of general distribution networks (i.e. partial estimation of the state of general distribution networks). To account for the possible inaccuracy of pseudo-load-measurement, the present invention includes methods for Real-time Load Demand Estimate (or Load Demand Estimate On-the-fly). In addition, the present invention also includes a 2/3 rule measurement-based method for correcting Pseudo-measurement.

### BRIEF DESCRIPTION OF THE DRAWINGS

A complete understanding of the present invention may be obtained by reference to the accompanying drawings, when considered in conjunction with the subsequent, detailed description, in which:

FIG. 1 shows an example of a general distribution network main feeder before the installation of CPMU. This illustration begins at the source 1006 and moves downstream along the main feeder line 1005 depicting a few nodes 1002, 1004. Each node 1002, 1004 has certain attachments 1008 that can be a load, a capacitor, a dispersed generator, or all three. Two of the nodes 1002 are branching nodes with laterals 1003 extending from each.

FIG. 2 shows placement of the first CPMU (i.e. PMU which measures current phasors) and one voltage phasor measurement unit (VPMU) (i.e. PMU which measures voltage phasors) at the source node (i.e. substation) of a distribution network. Three transmission lines meet at the source node. Here, the voltage phasor measurement unit and the current phasor measurement unit are strategically placed to measure and record data to be used for state estimation (SE).

FIG. 3 shows a CPMU installation on a branching node with attached dispersed generator (DG). This illustration is a more advanced variation of FIG. 2. It depicts the same characteristics as FIG. 2, but another node 1007 has been added on. This node 1007 serves as both a branching node and a node with a DG and shunt capacitor attached.

FIG. 4 shows an example of when a loop is present in the network. This depicts where a CPMU will be placed in the case where a loop is present in the network. A single CPMU will be needed to take appropriate measurements.

FIG. 5 shows an IEEE 14-bus test network, its one-line diagram and the locations for placing CPMUs, indicated by the rectangular blocks.

FIG. 6 shows an IEEE 37-bus test network, its one-line diagram and the locations for placing CPMUs, indicated by the rectangular blocks. This network was used as an example to show method for CPMU placement of the present invention.

FIG. 7 shows an example of a main feeder 1005 within the system. This is a very basic main feeder with no laterals. It depicts the power source 1006 and a few nodes 1004 with attachments. These attachments can range from loads, capacitors, and dispersed generators, all of which are accounted for in the algorithm for state estimation.

FIG. 8 shows an illustration of a basic branch showing the line between two nodes, a sending node and a receiving node and possible connecting devices to the two nodes (i.e. distribution line, switch, or transformer).

FIG. 9 shows a distribution line. This distribution line and variables are used in the equations for state estimation when a distribution line comes into play.

FIG. 10A shows a node with connected load and a shunt capacitor.

FIG. 10B shows a node with connected load, shunt capacitor, and a dispersed generator. A CPMU is placed at the interconnection of a node.

FIG. 11A shows a branch node with connected load and a shunt capacitor.

FIG. 11B shows a branch node with connected load, a shunt capacitor, and a dispersed generator.

FIG. 12 shows an example of a main feeder with a lateral. Similar to the regular main feeder, it depicts the power source and a few nodes with attachments. However, at node (l,k), a lateral extends out.

FIG. 13 shows how a CPMU removes a loop in an equivalent circuit. This figure shows the transformation from a loop to its equivalent radial circuit. The presence of the CPMU can separate the loop into an equivalent circuit.

FIG. 14 shows an IEEE 123-bus test network, its one-line diagram and the locations for placing PMUs.

### DESCRIPTION OF THE PREFERRED EMBODIMENT

The present invention explores the structure of distribution networks and shows that this option can be viable for state estimation of distribution networks.

The strategy of the method of the present invention for PMU placement begins by installing one PMU at the substation. This allows all synchronized measurements to be referred to a common angle reference, which is set to zero at the slack bus. According to some studies, the measurement uncertainties of PMU measurements are much smaller as compared with the conventional measurements. Redundancy analysis is performed within the method of the present invention for placing PMUs in order to ensure that a possible loss of a single measurement would not result in various critical measurements, affecting bad data detection. The present invention also proposes a method to ensure redundancy in PMU placements of the present invention.

It would be advantageous to provide a system for estimating the complete state of an unbalanced, radial or meshed power-distribution network with renewable energies in a real-time manner using a limited number of cost-effective measuring devices.

It would be advantageous to provide a system for monitoring an unbalanced, radial or meshed power-distribution network in a real-time manner using a limited number of cost-effective measuring devices.

It would also be advantageous to apply such a real-time system to a power-distribution network with renewable energies on an online, real-time control basis.

It would be further advantageous to apply such a real-time system to a power-distribution network with renewable energies to form the basis for advanced applications such as loss minimization, Volt/Var control, service restoration, and support of high-volume transfer of renewable energies in general distribution networks

It would be still further advantageous to apply such a real-time system to a power-distribution network as part of a power-restoration technique.

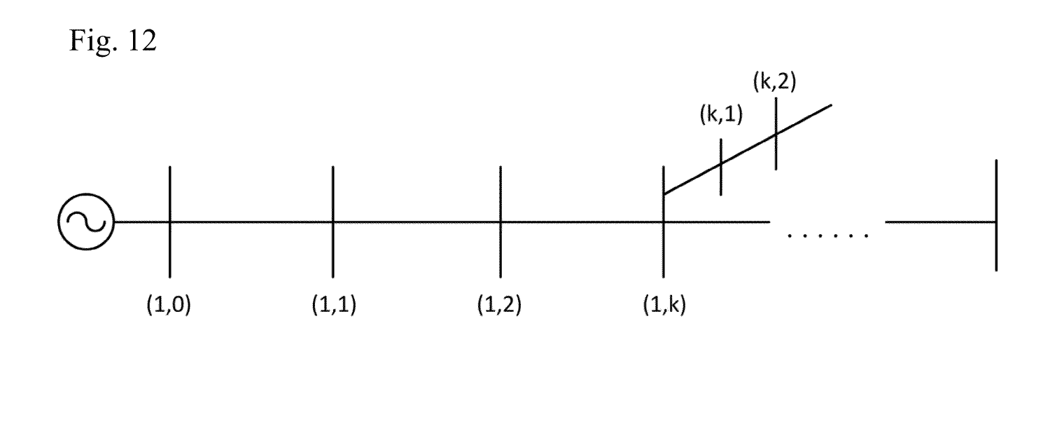

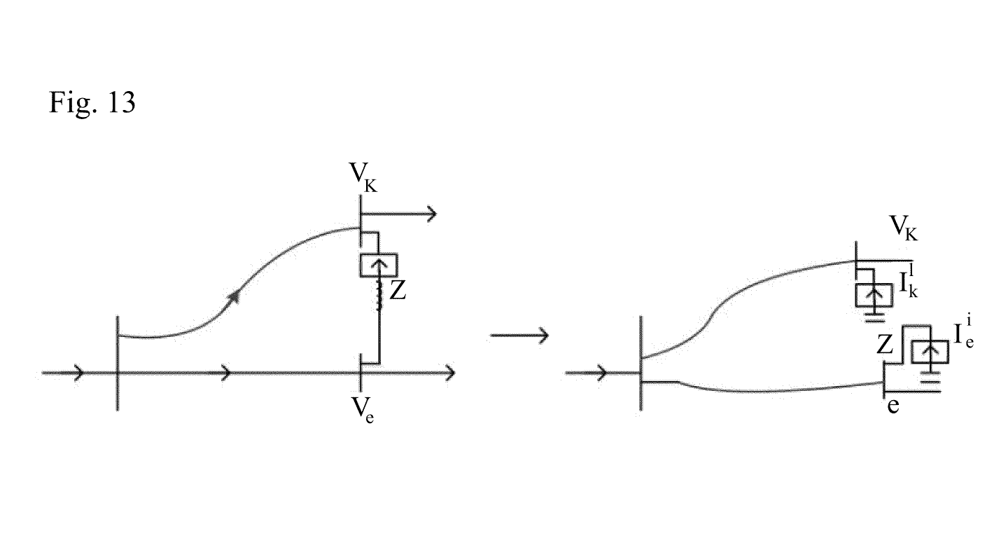

For purposes of this description, let N be the set of nodes in a distribution system, such as is shown in FIG. 12. Let k be a node index and Iₖ stand for the current phasor flow out of node k toward the downstream node of k along the main feeder. Vₖ stand for the voltage phasor at node k. The load representation of two, typical load models are described herein, the zero-inflated Poisson (ZIP) model where loads are modeled as a combination of constant impedance, constant current and constant power, and the exponential load model. All other, multiphase, grounded or ungrounded loads expressed in the form of either ZIP loads or exponential loads can be treated in this framework.

Traditionally, in addition to network data, a set of redundant measurements are required for traditional state estimators in order to estimate the system states. The measurement set includes the actual measurements taken on substations and feeders such as branch current, node voltages and branch power flows and the distribution transformer loadings obtained from historical data. However, the number of measurement devices installed in distribution networks is still low and insufficient for performing state estimation, i.e. the system may not be completely observable in the traditional sense.

Phasor Measurement Units (PMUs) provide the measurement of node voltage and or branch current phasors synchronized with a common time reference. The recent advances in accurate timing devices signal processing techniques and communication infrastructure have increased accuracy level of PMUs.

This invention describes a method of mostly using a low number of specialized measurement devices (i.e. CPMUs) along with the pseudo-measurement for load data, or/and real-time load data (when the advanced metering infrastructure (AMI) is available). Due to the cost of measurement and communication requirements, real-time load data of each node is still not available, despite recent advances in AMIs which can provide real-time load data of a small percentage of nodes along feeders. Loads in distribution networks are classified into three types: residential, industrial and commercial loads. Typical load pattern of each type of load can be obtained by electric load synthesis or load survey techniques. The load composition of each feeder or each lateral can be calculated based on the energy consumption of all loads served. It is known that pseudo measurements estimated by historical data usually do not match exactly with the (real-time) actual values. To resolve this issue, the present invention describes a method of using sparse measurements to correct the mismatch between pseudo-measurements and actual values.

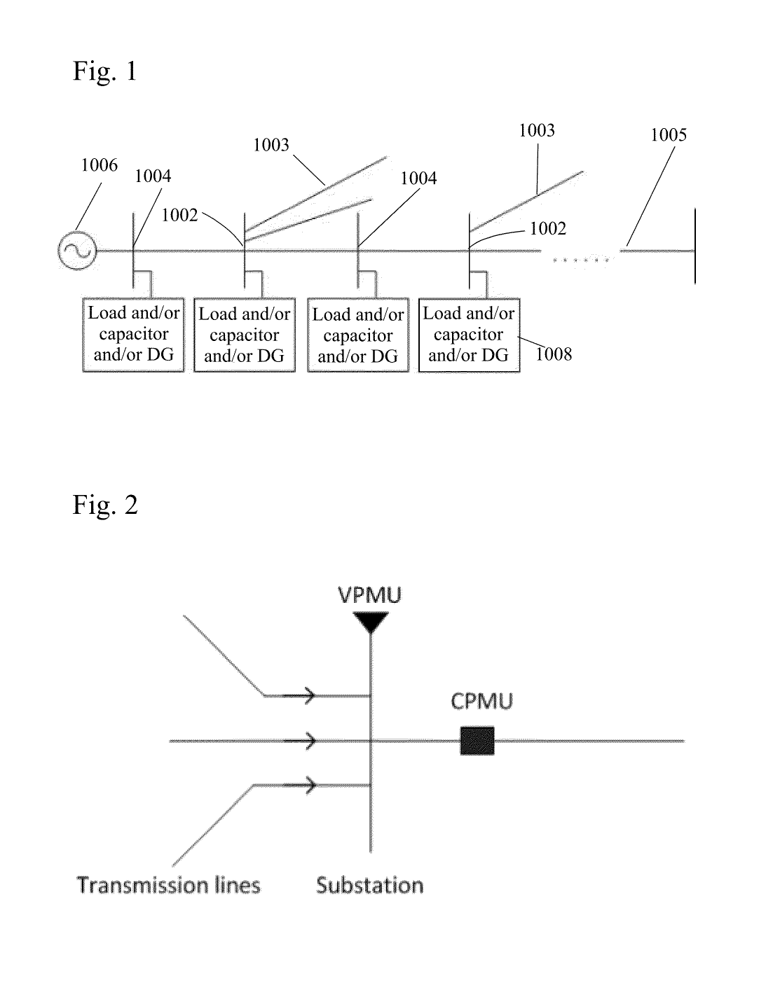

A general distribution network with a 3-phased unbalanced system that can have a high resistance to reactance ratio is considered (See FIG. 1). This invention develops methods for the placement of measurement devices and methods for real-time state estimation of distribution networks. A general distribution network can contain multiple branching nodes 1002 which are characterized by nodes connected to an injection line or a main feeder or main feeder line 1005 and two or more outgoing lines. A general distribution network can contain multiple loops, which are pathways with no dead end.

This invention contains: methods for placement of CPMU at appropriate locations of general distribution networks; direct and robust methods to estimate the state of general distribution networks; direct and robust methods to estimate a subset of the state of general distribution networks (i.e. partial estimation of the state of general distribution networks); methods for Real-time Load Demand Estimate (or Load Demand Estimate On-the-fly); a 2/3 rule measurement-based method for correcting Pseudo-measurement; and methods for Placing Current Phasor Measurement Unit (CPMU) for Radial Distribution Networks.

FIG. 1 shows an example of a general distribution network main feeder before the installation of CPMU. This illustration begins at the source 1006 and moves downstream along the main feeder line 1005 depicting a few nodes 1002, 1004. Each node 1002, 1004 has certain attachments 1008 that can be a load, a capacitor, a dispersed generator, or all three. Two of the nodes 1002 are branching nodes with laterals 1003 extending from each. The other two nodes are “regular” nodes and do not have any laterals branching from the node.

### Method of Placing Current Phasor Measurement Units (CPMU) for Radial Distribution

Consider a general distribution network with a radial structure. Without loss of generalization, we consider the network is composed of a main feeder with several laterals (see FIG. 1).

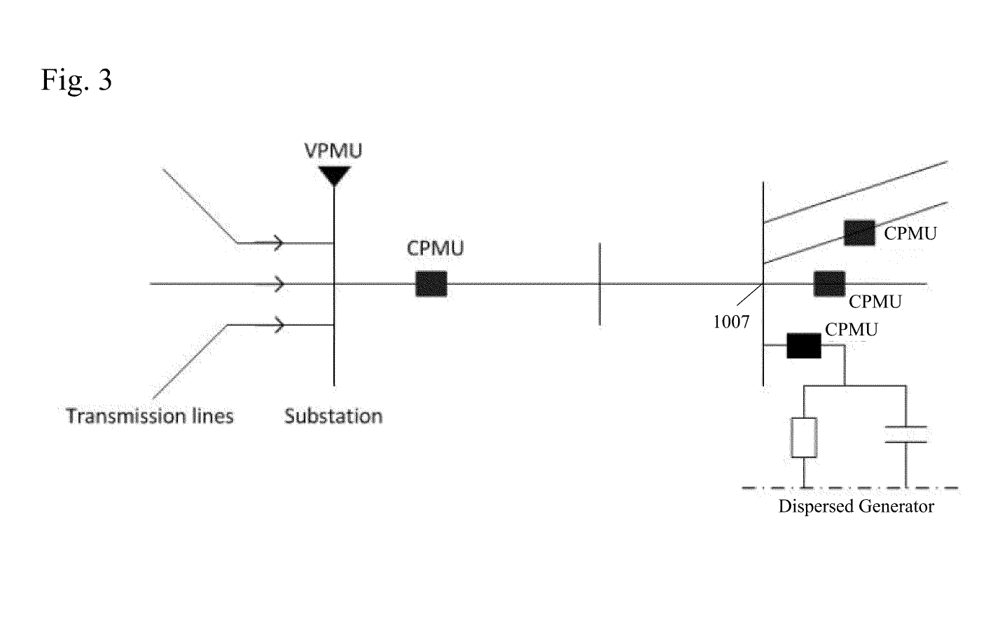

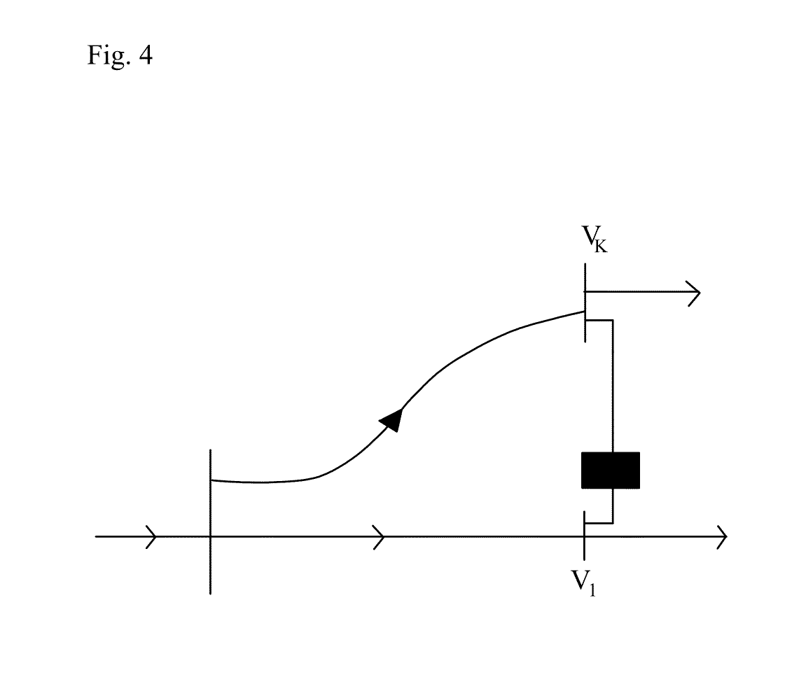

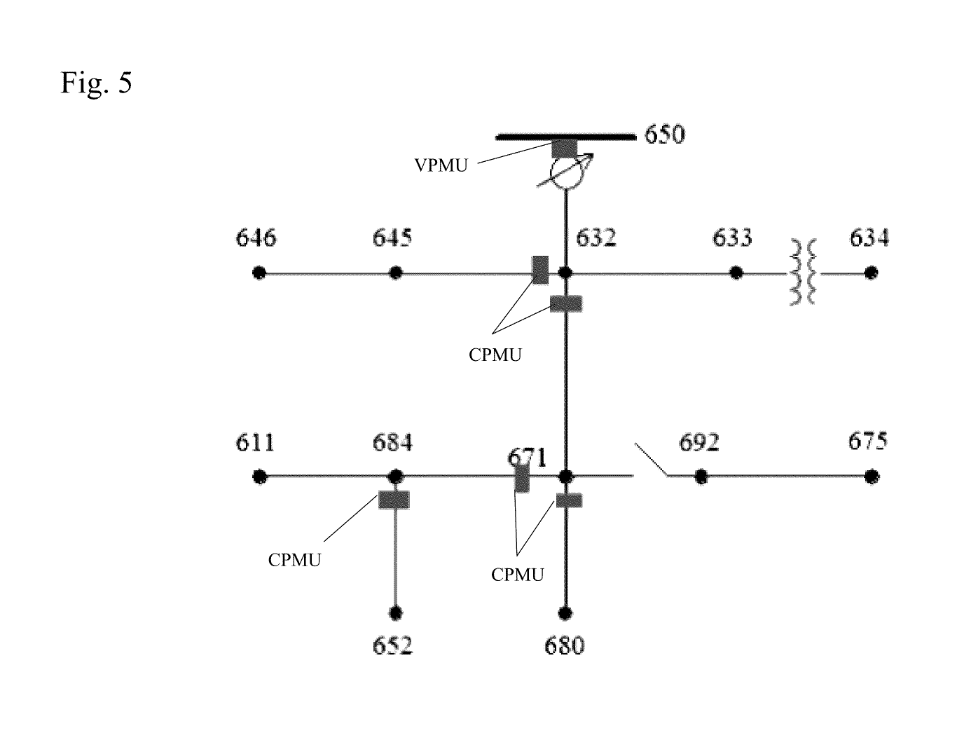

Step 0: Input a general radial distribution network with laterals.
Step 1: Identify the source (i.e. the substation) of the distribution network.
Step 2: Place a VPMU and a CPMU directly after source node (i.e. the substation node) to measure voltage and current phasor. For the sake of convenience, the voltage angle value at the source node is zero (See FIG. 2).
Step 3: Locate the next node, downstream of the source node along the main feeder line. For each located node, determine the type of node.
Step 4: If it is a regular node, or node that does not have any branches or laterals, then no CPMUs are needed; otherwise the node is a branching node and CPMUs are placed on all outgoing branches but one, and must include the outgoing branch of the main feeder to measure current phasors. In other words, all laterals of the branching node will have a CPMU except for one of the laterals. If there is only one lateral, a CPMU is placed on the one outgoing branch of the main feeder.
Step 5: Check whether the current node is the end node of the main feeder line. If yes, then advance to next step; otherwise, return to Step 3.
Step 6: Once all CPMUs have been installed, identify nodes with attached dispersed generators (DG).
Step 7: For each node with a DG present, place a CPMU on the line immediately downstream of the node with the DG present and the attached units, to measure current phasor injected by the DG, the load, and the capacitor into the node.
Step 8: Output the locations of PMU's placement to a controller and stop.
Methods for Placing Current Phasor Measurement Units (PM) for Weakly-meshed Distribution networks
Step 1: Identify all of the loops of the weakly meshed network.
Step 2: For an identified loop, isolate a line in the loop (which is preferred to be a line between the main feeder line and a lateral) between a node on the main feeder line and a node on the lateral branch and place a CPMU at one node of the line. The CPMU may be placed on either node, the node on the main feeder line or the node on the lateral branch. (see FIG. 4)
Step 3: Move to the next identified loop and repeat Step 2 until all loops in the network have had a CPMU placed.
Step 4: Identify the source (i.e. the substation) of the distribution network.
Step 5: Place a VPMU and a CPMU directly after a source node (i.e. the substation node) to measure voltage and current phasor. For the sake of convenience, the voltage angle value at the source node is zero.
Step 6: Locate the next node, downstream of the source node along the main feeder line. For each located node, determine the type of node.
Step 7: If it is a regular node, or node that does not have any branches or laterals, then no CPMUs are needed; otherwise the node is a branching node and CPMUs are placed on all outgoing branches but one, and must include the outgoing branch of the main feeder to measure current phasors. In other words, all laterals of the branching node will have a CPMU except for one of the laterals. If there is only one lateral, a CPMU is placed on the one outgoing branch of the main feeder.
Step 8: Check whether the current node is the end node of the main feeder line. If yes, then advance to next step; otherwise, return to Step 6.
Step 9: Once all the CPMUs have been installed, check each node for an attached dispersed generator (DG).
Step 10: If a DG is present, place a CPMU on the line to measure current phasor injected by the DG into the node.
Step 11: Check the next node for an attached DG. If one exists, repeat step 10; otherwise, stop.

### Real-Time State Estimation Method

Consider a general distribution network with radial structure. Without loss of generalization, we consider the network is composed of a main feeder with several laterals (see FIG. 1).

### Case A: A Main Feeder Case

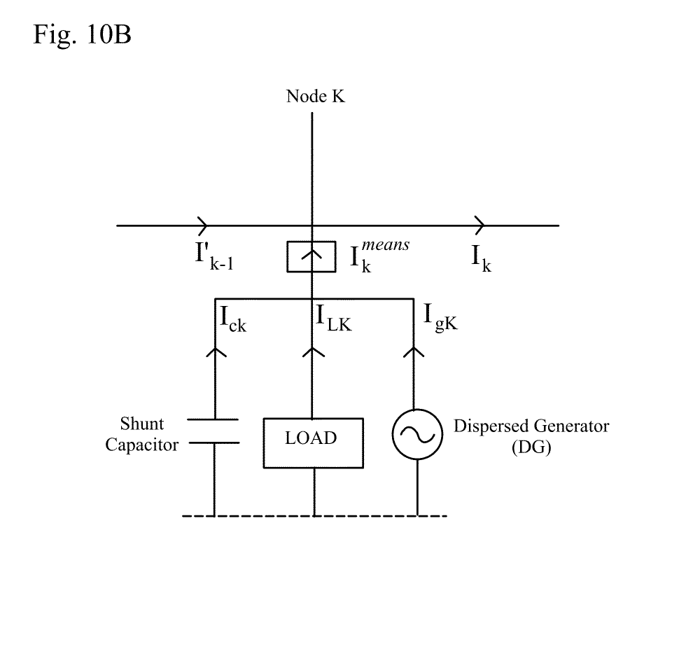

Step 1: Identify the source (i.e. the substation).
Step 2: From the phasor measurement at the substation, the voltage and current phasors at the source are V₀ and I₀ respectively and set k=0.
Step 3: Locate the next downstream node k+1 along the main feeder line.
Step 4: Identify the line between node k and node k+1 as a distribution line, or a switch, or a transformer.
Step 5: If a distribution line connects the two nodes (k, k+1), compute the voltage and current at node k+1 (see FIG. 9) as:

Vₖ₊₁=Vₖ−Zₖ*(Iₖ−0.5Yₖ*Vₖ)

I′ₖ₊₁=Zₖ⁻¹*(Vₖ₊₁−Vₖ)+0.5Yₖ₊₁*Vₖ₊₁

And go to Step 8; otherwise, skip to next step.
Step 6: If a switch exists between the two nodes (k, k+1), compute the voltage and current at node k+1 as:

Vₖ=Vₖ₊₁

Iₖ=I′ₖ₊₁

And go to Step 8; otherwise, skip to next step.
Step 7: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

I′ₖ₊₁=(Yₖ^{SP})*Vₖ+Yₖ^{SS}Vₖ₊₁

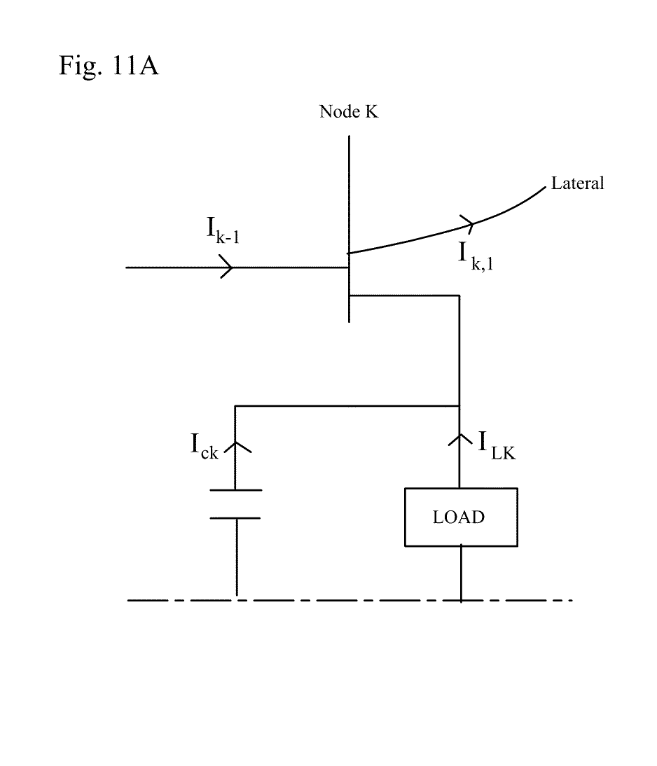

Step 8: Check if node k+1 has loads and/or shunt capacitors or a dispersed generator (DG) attached. If not, go to Step 12; otherwise, proceed to the next step.
Step 9: If loads and/or shunt capacitors are attached (see FIG. 10A), then

Iₖ₊₁=Iₖ₊₁+Iₖ₊₁ⁱ,

where

Iₖ₊₁ⁱ=I_{L}¹+I_{C}ⁱ

I_{L}ⁱ is the equivalent current injection from the attached loads when the node voltage is Vₖ₊₁

I_{C}ⁱ is the equivalent current injection from the attached shunt capacitors when the node voltage is Vₖ₊₁

Step 10: If a DG is attached, then Iₖ₊₁=I′ₖ₊₁+Iₖ₊₁^{meas}, where Iₖ₊₁^{meas} is the measured current phasor injection into node k+1 (see FIG. 10B).
Step 11: If no DGs are attached, then Iₖ₊₁=I′ₖ₊₁.
Step 12: Check if the node k+1 is the end node of the main feeder line. If not, set k=k+1 and go to Step 3; otherwise, proceed to next step
Step 13: If |Iₖ₊₁|≦ε (extremely small number), then stop and output the state estimation results to a controller; otherwise, distribute Iₖ₊₁ uniformly to each load of the main feeder line and return to Step 2 with k=0. It should be noted that not all of the nodes need to be examined.
Case B: A Main Feeder with Laterals

(Without loss of generality, each branching node along the main feeder has only one lateral)

Step 1: Identify the source (i.e. the substation).
Step 2: From the phasor measurement at the substation, the voltage and current phasors at the source are V₀ and I₀ respectively and set k=0.
Step 3: Locate the next downstream node k+1 along the main feeder line.
Step 4: Identify the line between node k and node k+1 as a distribution line, or a switch, or a transformer.
Step 5: If a distribution line connects the two nodes (k, k+1), compute the voltage and current at node k+1 as:

Vₖ₊₁=Vₖ−Zₖ*(Iₖ−0.5Yₖ*Vₖ)

Iₖ₊₁=Zₖ⁻¹*(Vₖ₊₁−Vₖ)+0.5Yₖ₊₁*Vₖ₊₁

And go to Step 8; otherwise, skip to next step.
Step 6: If a switch exists between the two nodes (k, k+1), compute the voltage and current at node k+1 as:

Vₖ=Vₖ₊₁

Iₖ=−Iₖ₊₁

And go to Step 8; otherwise, skip to next step.
Step 7: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

I′₊₁=(Yₖ^{SP})*Vₖ+Yₖ^{SS}Vₖ₊₁

Step 8: If node k+1 is a branching node, then go to Step 14; otherwise, check if node k+1 has loads and/or shunt capacitors or a dispersed generator (DG) attached. If not, go to Step 12; otherwise, proceed to the next step.
Step 9: If loads and/or shunt capacitors are attached, then

Iₖ₊₁=−I′ₖ₊₁+Iₖ₊₁ⁱ,

where

Iₖ₊₁ⁱ=I_{L}ⁱ+I_{C}ⁱ

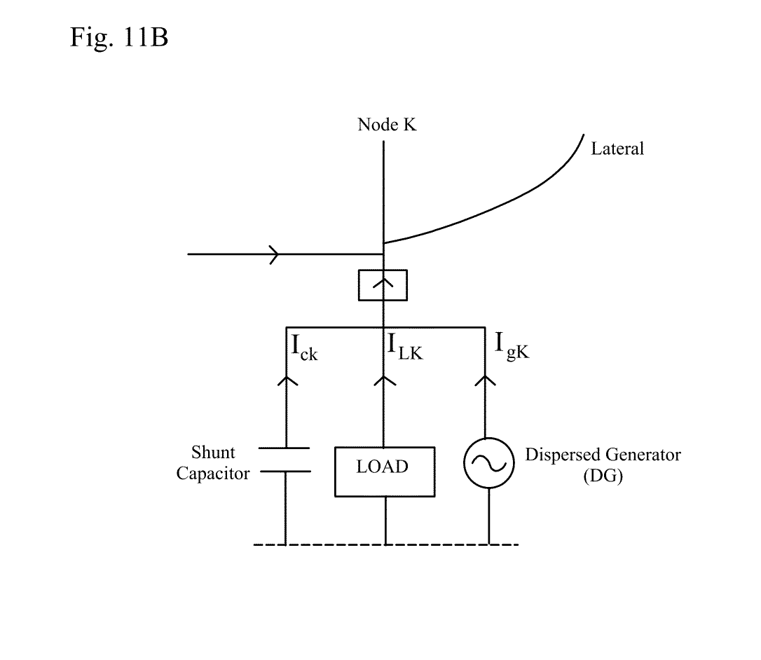

I_{L}ⁱ is the equivalent current injection from the attached loads when the node voltage is Vₖ₊₁
I_{C}ⁱ is the equivalent current injection from the attached shunt capacitors when the node voltage is Vₖ₊₁
Step 10: If a DG is attached, then Iₖ₊₁=−I′ₖ₊₁+Iₖ₊₁^{meas}, where Iₖ₊₁^{meas} the measured current phasor injection into node k+1.
Step 11: If no DGs are attached, then Iₖ₊₁=−I′ₖ₊₁.
Step 12: Check if the node k+1 is the end node of the main feeder line. If not, set k=k+1 and go to Step 3; otherwise, proceed to next step.
Step 13: If |Iₖ₊₁|≦ε (extremely small number), then go to Step 3; otherwise, distribute Iₖ₊₁ uniformly to each load of the main feeder line and return to Step 3 with k=0.
Step 14: For node k+1, let Iₖ₊₁=Iₖ₊₁^{meas}, as measured by its CPMU.
Step 15: If loads and/or shunt capacitors are attached but no DGs are attached (see FIG. 11(A), then the current phasor, I_{k+1,1,} injected into the lateral from the branching node k+1 is

I_{k+1,1}=−I′ₖ₊₁+Iₖ₊₁ⁱ−Iₖ₊₁^{meas},

where

I₊₁ⁱ=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁

Then skip to Step 3.

Step 16: If a DG is attached (see FIG. 11(B), then the current phasor, I_{k+1,1,} injected into the lateral from the branching node k+1 is

I_{k+1,1}=−I′ₖ₊₁−Iₖ₊₁^{meas}

Then skip to Step 3.

Step 17: If no DGs are attached, then compute the downstream current with:

Iₖ₊₁=Iₖ₊₁^{meas}

Then skip to Step 3.

Step 18: For each lateral originating from branching node k, set V₀=Vₖ and I₀=I_{k,1} and set k=0.
Step 19: Locate the next downstream node k+1 along the lateral extending from branching node.
Step 20: Identify the line between node k and node k+1 as a distribution line, or a switch, or a transformer.
Step 21: If a distribution line connects the two nodes (k, k+1), compute the voltage and current at node k+1 as:

Vₖ₊₁=Vₖ−Zₖ*(Iₖ−0.5Yₖ*Vₖ)

I′ₖ₊₁=Zₖ⁻¹*(Vₖ₊₁−Vₖ)+0.5Yₖ₊₁*Vₖ₊₁

And go to Step 24; otherwise, skip to next step.
Step 22: If a switch exists between the two nodes (k, k+1), compute the voltage and current at node k+1 as:

Vₖ=Vₖ₊₁

Iₖ=−I′ₖ₊₁

And go to Step 24; otherwise, skip to next step.
Step 23: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

I′ₖ₊₁=(Yₖ^{SP})*Vₖ+Yₖ^{SS}Vₖ₊₁

Step 24: If node k+1 has loads and/or shunt capacitors or a dispersed generator (DG) attached, proceed to the next step; otherwise, go to Step 27
Step 25: If loads and/or shunt capacitors are attached, then

Iₖ₊₁=−I′ₖ₊₁+Iₖ₊₁ⁱ,

where

Iₖ₊₁ⁱ=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁
Step 26: If a DG is attached, then Iₖ₊₁=−I′ₖ₊₁+Iₖ₊₁^{meas}, where Iₖ₊₁^{meas} is the measured current phasor injection into node k+1.
Step 27: If no DGs are attached, then Iₖ₊₁=−I′₊₁.
Step 28: Check if the node k+1 is the end node of lateral. If not, set k=k+1 and go to Step 19; otherwise, proceed to next step
Step 29: If |Iₖ₊₁|≦ε (extremely small number), then go to next Step; otherwise, distribute Iₖ₊₁ uniformly to each load of lateral and return to Step 19 with k=0.
Step 30: When the states of all laterals are estimated, then output the state estimation results to a controller and stop; otherwise go to Step 18.
Case C: General Weakly-Meshed Distribution Networks with Laterals

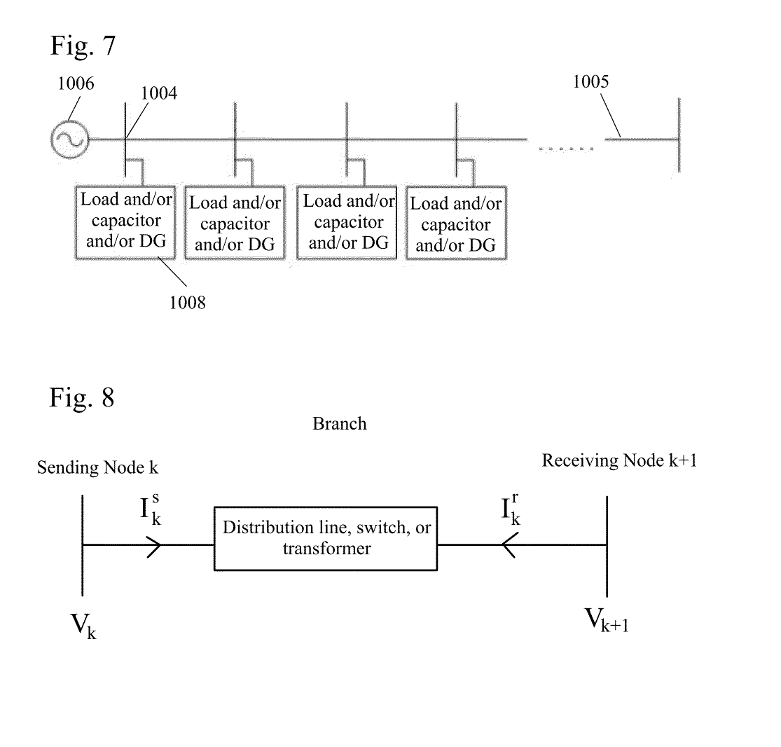

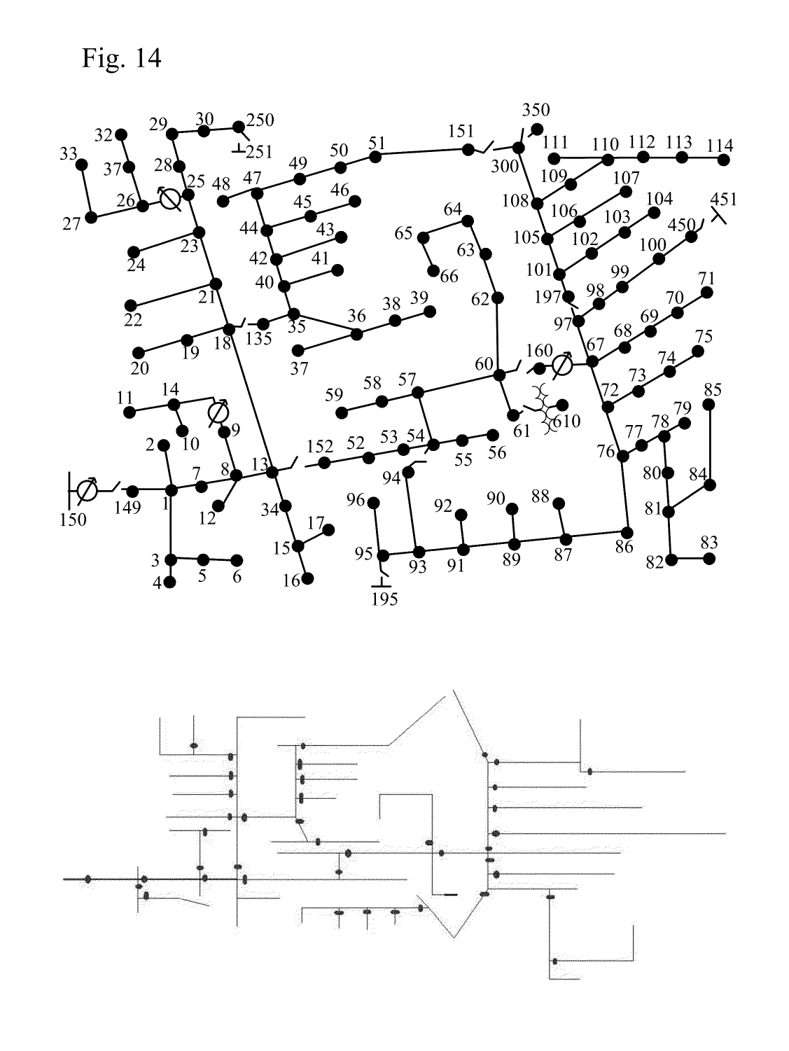

As illustrated by FIGS. 6 and 14, the present invention describes a method of placing a CPMU on a loop and removing a line in the loop by injecting equivalent current into both end nodes of the line. After replacing a line in a loop by two equivalent current injections, the meshed distribution network is transformed into a radial distribution network with equivalent current injections. We note that the nodes in a loop are termed in this invention as “loop nodes”.

Step 1: Identify the source (i.e. the substation).
Step 2: From the phasor measurement at the substation, the voltage and current phasors at the source are V₀ and I₀ respectively and set k=0.
Step 3: Identify all the loops in the weakly-meshed network.
Step 4: For each loop, do the following:
Step 4.1: Detect the line with a CPMU in the loop set between nodes k and m (node k and node m are referred to as loop nodes).(See FIG. 4 between node k and node m) Let the impedance of the line be Z_{k,m} and admittance Y_{k,m}. Let the CPMU reading from the loop between nodes k and m into node k be I_{k,m}^{meas}.
Step 4.2: Compute the equivalent current injection due to the loop Iₖ^{i,l} at node k and Iₘ^{i,l} at node m using the following formula,

Iₖ^{i,l}=_{k,m}^{meas}

Iₘ^{i,l}=−(Z_{k,m}⁻¹*(Vₘ−Vₖ)+0.5Y_{k,m}*(Vₖ−Z_{k,m}*(−I_{k,m}^{meas}−0.5Y_{k,m}*Vₖ))

Step 5: Locate the next downstream node k+1 along the main feeder line.
Step 6: Identify the line between node k and node k+1 as a distribution line, or a switch, or a transformer.
Step 7: If a distribution line connects the two nodes (k, k+1), compute the voltage and current at node k+1 as:

Vₖ₊₁=Vₖ−Zₖ*(Iₖ−0.5Yₖ*Vₖ)

I′ₖ₊₁=Zₖ⁻¹*(Vₖ₊₁−Vₖ)+0.5Yₖ₊₁*Vₖ₊₁

And go to Step 10; otherwise, skip to next step.
Step 8: If a switch exists between the two nodes (k, k+1), compute the voltage and current at node k+1 as:

Vₖ=Vₖ₊₁

Iₖ=−I′ₖ₊₁

And go to Step 10; otherwise, skip to next step.
Step 9: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

Iₖ₊₁=(Yₖ^{SP})*Vₖ+Yₖ^{SS}Vₖ₊₁

Step 10: If node k+1 is a branching node, then go to Step 16; otherwise, perform the following:
Step 10(a): If node k+1 is a loop node, then −I′ₖ₊₁=−I′ₖ₊₁+Iₖ₊₁^{i,l}, where Iₖ₊₁^{i,l}=I_{k+1,m}^{meas} (or =−(Z_{k+1,m}⁻¹*(Vₘ−Vₖ₊₁)+0.5Y_{k+1,m}*(Vₖ₊₁−Z_{k+1,m}*(−Iₖ₊₁^{meas}−0.5Y_{k+1,m}*Vₖ₊₁))), depending on whether the measurement of the loop is taken at node k+1 or not as explained in Step 4.
Step 10(b): Check if node k+1 has loads and/or shunt capacitors or a dispersed generator (DG) attached. If not, go to Step 14; otherwise, proceed to the next step.
Step 11: If loads and/or shunt capacitors are attached to node k+1, then

Iₖ₊₁=−I′ₖ₊₁+Iₖ₊₁ⁱ,

where

Iₖ₊₁ⁱ=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁
Step 12: If a DG is attached, then Iₖ₊₁=−I′ₖ₊₁+Iₖ₊₁^{meas} , where Iₖ₊₁^{meas} is the measured current phasor injection into node k+1.
Step 13: If no DGs are attached, then Iₖ₊₁=−I′ₖ₊₁.
Step 14: Check if the node k+1 is the end node of the main feeder line. If not, set k=k+1 and go to Step 5; otherwise, proceed to next step.
Step 15: If E (extremely small number), then go to Step 5; otherwise, distribute Iₖ₊₁ uniformly to each load of the main feeder line and return to Step 5 with k=0.
Step 16: For node k+1, let Iₖ₊₁=Iₖ₊₁^{meas}, as measured by its CPMU. If node k+1 is a loop node, then −I′ₖ₊₁=−I′ₖ₊₁+Iₖ₊₁^{i,l}, where Iₖ₊₁^{i,l}=I_{k+1,m}^{meas} (or =−(Z_{k+1,m}⁻¹*(Vₘ−Vₖ₊₁)+0.5Y_{k+1,m}*(Vₖ₊₁−Z_{k+1,m}*(−I_{k+1,m}^{meas}−0.5Y_{k+1,m}*Vₖ₊₁))), depending on whether the measurement of the loop is taken at node k+1 or not as explained in Step 4.
Step 17: If loads and/or shunt capacitors are attached but no DGs are attached , then the current phasor, I_{k+1,1,} injected into the lateral from the branching node k+1 is

I_{k+1,1}=−I′ₖ₊₁+Iₖ₊₁ⁱ−Iₖ₊₁^{meas},

where

Iₖ₊₁ⁱ+I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁

Then skip to Step 5.

Step 18: If a DG is attached, then the current phasor, I_{k+1,1,} injected into the lateral from the branching node k+1 is

I_{k+1,1}=−I′ₖ₊₁−Iₖ₊₁^{meas}

Then skip to Step 5.

Step 19: If none are attached, then compute the downstream current with:

Iₖ₊₁=Iₖ₊₁^{meas}

Then skip to Step 5.

Step 20: For each lateral, say originating from branching node k, set V₀=Vₖ and I₀=I_{k,1} and set k=0.
Step 21: Locate the next downstream node k+1 along the lateral extending from branching node.
Step 22: Identify the line between node k and node k+1 as a distribution line, or a switch, or a transformer.
Step 23: If a distribution line connects the two nodes (k, k+1), compute the voltage and current at node k+1 as:

Vₖ₊₁=Vₖ−Zₖ*(Iₖ−0.5Yₖ*Vₖ)

I′ₖ₊₁=Zₖ⁻¹*(Vₖ₊₁−Vₖ)+0.5Yₖ₊₁*Vₖ₊₁

And go to Step 26; otherwise, skip to next step.
Step 24: If a switch exists between the two nodes (k, k+1), compute the voltage and current at node k+1 as:

Vₖ=Vₖ₊₁

Iₖ=−i′ₖ₊₁

And go to Step 26; otherwise, skip to next step.
Step 25: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

I′ₖ₊₁=(Yₖ^{SP})*Vₖ+Yₖ^{SS}Vₖ₊₁

Step 26: If node k+1 is a loop node, then −I′ₖ₊₁=−I′ₖ₊₁+Iₖ₊₁^{i,l}, where Iₖ₊₁^{i,l}=I_{k+1,m}^{meas} (or=−(Zₖ₊₁⁻¹*(Vₘ−Vₖ₊₁)+0.5Y_{k+1,m}*(Vₖ₊₁−Z_{k+1,m}*(−I_{k+1,m}^{meas}−0.5Y_{k+1,m}*Vₖ₊₁))), depending on whether the measurement of the loop is taken at node k+1 or not as explained in Step 4. If node k+1 has loads and/or shunt capacitors or a dispersed generator (DG) attached, proceed to the next step; otherwise, go to Step 29.
Step 27: If loads and/or shunt capacitors are attached, then

Iₖ₊₁=I′ₖ₊₁+Iₖ₊₁ⁱ,

where

Iₖ₊₁=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁
Step 28: If a DG is attached, then Iₖ₊₁=−I′ₖ₊₁+Iₖ₊₁^{meas}, where Iₖ₊₁^{meas} is the measured current phasor injection into node k+1.
Step 29: If no DGs are attached, then Iₖ₊₁=−I′ₖ₊₁.
Step 30: Check if the node k+1 is the end node of lateral. If not, set k=k+1 and go to Step 21; otherwise, proceed to next step.
Step 31: If |Iₖ₊₁|≦ε (extremely small number), then go to next Step; otherwise, distribute Iₖ₊₁ uniformly to each load of lateral and return to Step 21 with k=0.
Step 32: When the states of all laterals are estimated, then output the state estimation results to a controller and stop; otherwise go to Step 20.

### A 2/3 Rule Measurement-Based Method For Correcting Pseudo-Measurement

Most pseudo-measurements used in modern distribution networks are forecasted loads. The data used to forecast the loads is historical data and is not the most accurate. The present invention discloses a method of improving the accuracy of the pseudo-measurements in the network based on additional measurements. If some AMI information is available, the invented method is still applicable if the pseudo-measurements are replaced by the corresponding AMI information.

The invented 2/3 Rule of pseudo-measurement correction method is described as follows:

Step 1: Identify the source (i.e. the substation).
Step 2: Locate the next downstream node k+1 along the main feeder line.
Step 3: Calculate the load current into this node.
Step 4: Keep a running calculation of the loads measured (replace the calculation by the corresponding AMI, if it is available).
Step 5: If all loads have been accounted for on the main feeder line, proceed to next step; otherwise, move downstream to the next node and repeat step 3.
Step 6: Identify the point on the main feeder line that comes after 2/3 of the all of the loads.
Step 7: Place a VPMU and a CPMU on the 2/3 load point.
Step 8: Apply the method for real-time to perform state estimation of the present invention discussed above for nodes downstream of the 2/3 load point.
Step 9: For the area between the source node and the 2/3 load point, derive an equivalent circuit.

### Solve V₁,V₂,V₃, . . . V_{(2/3)}

Solve for each load by α

### Apply V₁(α),V₂(α),V₃(α), . . . V_{(2/3)}(α)

Solve minimum

$$α \{ {\vert {V}_{( \frac{2}{3} )} ( α ) - {V}_{( \frac{2}{3} )}^{meas} \vert}^{2} + W {\vert {I}_{( \frac{2}{3} )} ( α ) - {I}_{( \frac{2}{3} )}^{meas} \vert}^{2} \}$$

with W as α*

Step 10: Use α* as the scaling factor Vᵢ(α*) and the pseudo-measurement load is scaled by the scaling factor.

### Redundancy Analysis

A measurement is classified as either critical or redundant. Redundant measurements can be removed from the measurement system without causing the system to become unobservable. When a redundant measurement is erroneous, this can be detected by statistical tests based on measurement residuals. Removal of critical measurements, however, will lead to an unobservable system, and errors in these types of measurements cannot be detected. A well-designed measurement system should not contain any critical measurements so that bad data is processed. By adding a few measurements at the proper locations, one can avoid critical measurements which may lead to bad data being processed.

Redundancy analysis is performed on the method of the present invention for placing PMUs in order to ensure that a possible loss of a single measurement would not result in critical measurements and thus prevent bad data detection. The present invention also proposes a method for ensuring redundancy in PMU placements as discussed above.

To ensure redundancy, the method of the present invention for placing PMUs is extended as follows:

At each branching node, place PMUs at each outgoing branch and at an incoming branch.

At each looping branch, place one PMU at each end of the looping branch to ensure a redundancy.

Without loss of generality, only a method for Placing Current Phasor Measurement Units (CPMUs) for Weakly-meshed Distribution networks with redundancy is presented below. The invented method is applicable to general distribution networks within the scope of the present invention.

Step 1: Identify all of the loops of the weakly meshed network.
Step 2: For an identified loop, isolate a line in the loop (which is preferred to be a line between the main feeder line and a lateral) between the two nodes and place a CPMU at each node of the line.
Step 3: Move on to the next identified loop and repeat Step 2 until all loops in the network have been handled.
Step 4: Identify the source (i.e. the substation) of the distribution network.
Step 5: Place a PMU and a CPMU directly after source node (i.e. the substation node) to measure voltage and current phasor. For the sake of convenience, the voltage angle value at the source node is zero.
Step 6: Locate the downstream node along the main feeder line and determine type of node.
Step 7: If it is a regular node, or node that does not have any branches or laterals, then no CPMUs are needed; otherwise the node is a branching node and CPMUs are placed on all outgoing branches but one, and must include the outgoing branch of the main feeder to measure current phasors. In other words, all laterals of the branching node will have a CPMU except for one of the laterals. If there is only one lateral, a CPMU is placed on the one outgoing branch of the main feeder.
Step 8: Check whether the current node is the end node of the main feeder line. If yes, then advance to next step; otherwise, return to Step 6.
Step 9: For each node with an attached dispersed generator (DG), place a CPMU on the line to measure current phasor injected by the DG into the node.
Step 10: Check the next node for an attached DG. If one exists, repeat step 9; otherwise, stop.

### Partial State Estimation

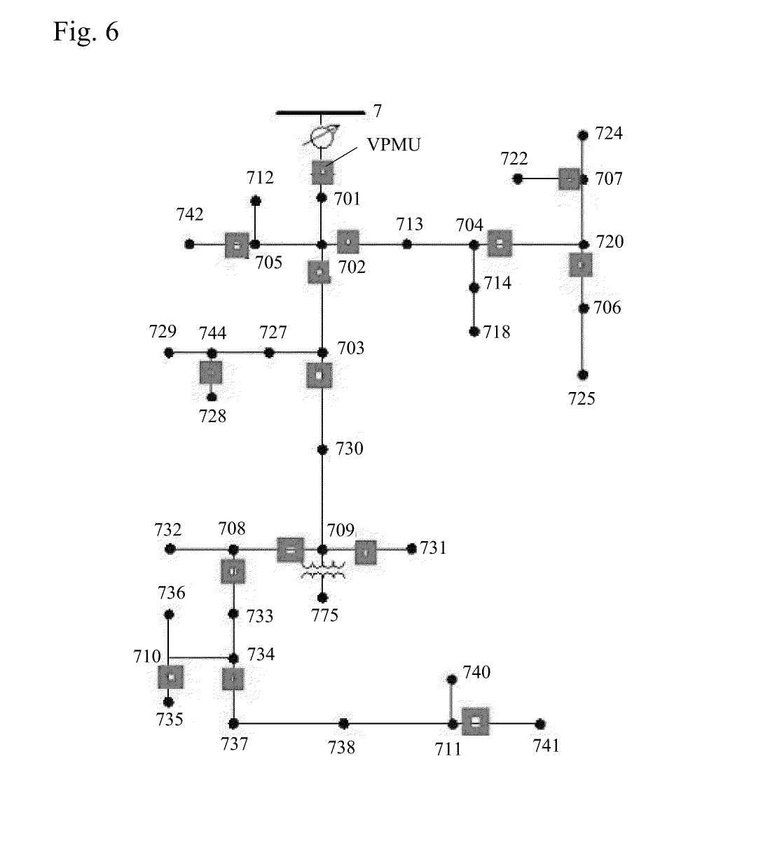

In some cases, when conducting state estimation, not every single detail is known or necessary to monitor the system. Certain laterals may be not as important and hence, can be ignored for the sake of practical applications. Sometimes, there is also not enough sufficient data available to make accurate estimations. During these cases, we place a measurement unit at the beginning of the branch to measure the outgoing current phasor. This serves as a way to produce a branch equivalent which is taken into account when doing the overall state estimation. FIG. 5 depicts the IEEE 14-bus test network with location of CPMUs. Using this network as an example, and assuming the line from bus 684 to 652 has unavailable data, the CPMU placed there can measure the constant current vector and create a branch equivalent. This data on the current phasor will then be taken into the calculation of the overall system.

The following method is used for such situations and for deriving partial state estimation. It should be noted that the methods are applicable to the following: Methods for real-time partial state estimation for Radial Distribution Networks and Methods for real-time partial state estimation for Weakly-meshed Distribution networks.

Step 1: Identify the source (i.e. the substation).
Step 2: Locate the next downstream branching node k+1.
Step 3: Determine if the branching node is needed for state estimation (a branch is not needed if sufficient data on the branch node is unavailable).
Step 4: If the branch is needed, move on to the next step. If the branch is not needed, place a PMU to measure constant current and return to step 2.
Step 5: For node k+1, let Iₖ₊₁=Iₖ₊₁^{meas}, as measured by its CPMU.
Step 6: If loads and/or shunt capacitors are attached but no DGs are attached (see FIG. 11(A), then the current phasor, I_{k+1,1,} injected into the lateral from the branching node k+1 is

I_{k+1,1}=−I′ₖ₊₁+Iₖ₊₁ⁱ−Iₖ₊₁^{meas},

where

Iₖ₊₁ⁱ=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁

Then skip to Step 2.

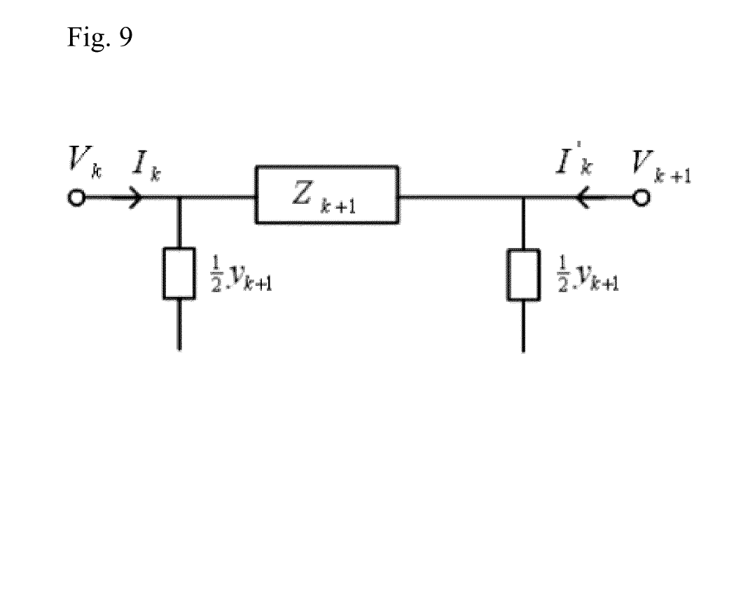

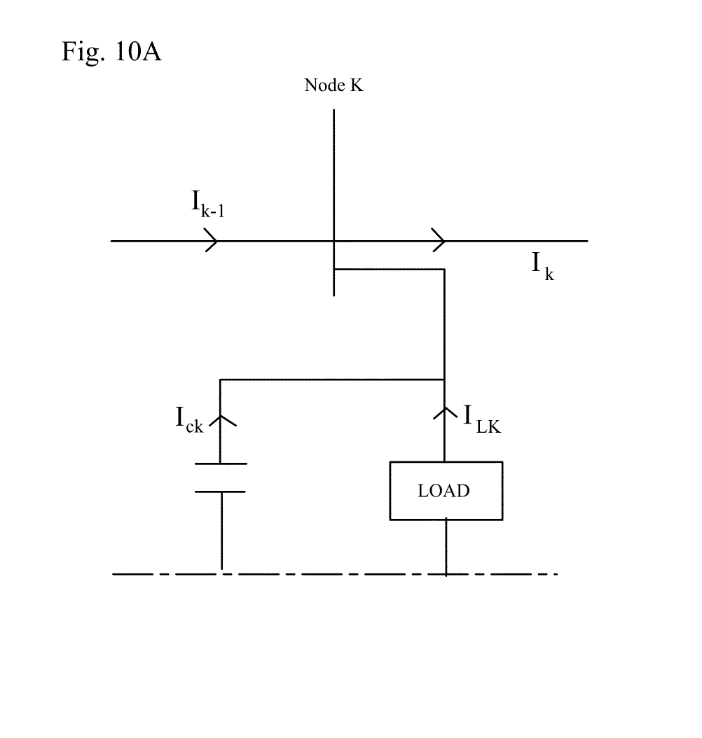

Step 7: If a DG is attached (see FIG. 7), then the current phasor, I_{k+1,1}, injected into the lateral from the branching node k+1 is

I_{k+1,1}=−I′ₖ₊₁−Iₖ₊₁^{meas}

Then skip to Step 2.

Step 8: If no DGs are attached, then compute the downstream current with:

Iₖ₊₁=Iₖ₊₁^{meas}

Then skip to Step 2.

Step 9: For each lateral, say originating from branching node k, set V₀=Vₖ and I₀=I_{k,1} and set k=0.
Step 10: Locate the next downstream node k+1 along the lateral extending from the branching node.
Step 11: Identify the line between node k and node k+1 as a distribution line, or a switch, or a transformer.
Step 12: If a distribution line connects the two nodes (k, k+1), compute the voltage and current at node k+1 as:

Vₖ₊₁=Vₖ−Zₖ*(Iₖ−0.5Yₖ*Vₖ)

I′ₖ₊₁=Zₖ⁻¹*(Vₖ₊₁−Vₖ)+0.5Yₖ₊₁*Vₖ₊₁

And go to Step 15; otherwise, skip to next step.
Step 13: If a switch exists between the two nodes (k, k+1), compute the voltage and current at node k+1 as:

Vₖ=Vₖ₊₁

Iₖ=−I′ₖ₊₁

And go to Step 15; otherwise, skip to next step.
Step 14: If a transformer exists between the two nodes (k, k+1) with the admittance matrix,

$$[ \begin{matrix}{Y}_{k}^{PP} & {Y}_{k}^{PS} \\ {Y}_{k}^{SP} & {Y}_{k}^{SS}\end{matrix} ] ,$$

compute the voltage and current at node k+1 as:

Vₖ₊₁=(Yₖ^{SP})⁻¹*(Iₖ−Yₖ^{PP}Vₖ)

I′ₖ₊₁=(Yₖ^{SP})*Vₖ+Yₖ^{SS}Vₖ₊₁

Step 15: If node k+1 has loads and/or shunt capacitors or a dispersed generator (DG) attached, proceed to the next step; otherwise, go to Step 18
Step 16: If loads and/or shunt capacitors are attached, then

Iₖ₊₁=−I′ₖ₊₁+I₊₁ⁱ,

where

Iₖ₊₁ⁱ=I_{L}ⁱ+I_{C}ⁱ

I_{L}ⁱ is the equivalent current injection from the attached loads when the node voltage is Vₖ₊₁
I_{C}ⁱ is the equivalent current injection from the attached shunt capacitors when the node voltage is Vₖ₊₁
Step 17: If a DG is attached, then Iₖ₊₁=−I′ₖ₊₁+Iₖ₊₁^{meas}where Iₖ₊₁^{meas} the measured current phasor injection into node k+1.
Step 18: If no DGs are attached, then Iₖ₊₁=−I′ₖ₊₁.
Step 19: Check if the node k+1 is the end node of the lateral. If not, set k=k+1 and go to Step 10; otherwise, proceed to next step.
Step 20: If |Iₖ₊₁|≦ε (extremely small number), then go to next Step; otherwise, distribute Iₖ₊₁ uniformly to each load of lateral and return to Step 10 with k=0.
Step 21: When the states of all laterals are estimated, then output the state estimation results to a controller and stop; otherwise go to Step 9.

### Real-time Load Demand Estimate (or Load Demand Estimate On-the-fly)

The algorithms and methods preceding this all assume that the loads are known. However, that is not always the case. The following is a method used to determine load demands of a given system.

Step 1: For each lateral, obtain the actual injected (real or reactive) power into the lateral, Pᵢ⁰ (t), Qᵢ⁰(t) by using the measured current phasor in the lateral multiplied by the computed voltage phasor at the branching node.
Step 2: Assume an initial power loss for each lateral, say P_{i,loss}⁰, Q_{i,loss}^{o}(t), and subtract losses from the actual power. (Real Pᵢ^{o}(t), Reactive P_{i,loss}⁰(t) Qᵢ⁰(t)−Q_{i,loss}⁰(t)).
Step 3: For each node of the lateral, obtain load types, average daily (real and reactive) demands (Real ADDP_{i,j}, Reactive ADDQ_{i,j}), and class-specific load estimate factor (LEF: Real LEFP_{i,j}(t), Reactive LEFQ_{i,j}(t)).
Step 4: For each lateral, say lateral i, obtain the real load demand estimate of each node on the lateral.

$${P}_{i , j} ( t ) = ( {P}_{i}^{0} ( t ) - {P}_{i , loss}^{0} ( t ) ) * ( \frac{{LEFP}_{i , j} ( t ) * {ADDP}_{i , j}}{{\sum }_{j = 0}^{n} ( {LEFP}_{i , j} ( t ) * {ADDP}_{i , j} )} )$$

Step 5: For each lateral i, also obtain the reactive load demand estimate of each node on the lateral.

$${Q}_{i , j} ( t ) = ( {Q}_{i}^{0} ( t ) - {Q}_{i , loss}^{0} ( t ) ) * ( \frac{{LEFQ}_{i , j} ( t ) * {ADDQ}_{i , j}}{{\sum }_{j = 0}^{n} ( {LEFQ}_{i , j} ( t ) * {ADDQ}_{i , j} )} )$$

### Numerical Studies

We consider the IEEE 14 bus distribution test feeder shown in FIG. 5. By applying the invented method for placing CPMUs on radial distribution networks, the locations of the IEEE 14 bus that need the placement of CPMUs are highlighted in FIG. 5. A total of 6 CPMUs and 1 VPMU at the substation (i.e. bus 650) are needed. By applying the invented method for real-time state estimation for radial distribution networks, the state estimation results were compared with the benchmark results which were obtained by the power flow computation in Table 1. The very small error indicates the accuracy of the invented method on this small test system.

TABLE 1
The state estimation results were compared with the benchmark
results which were obtained by the power flow computation.

| | Power flow | State estimation | |
|---|---|---|---|
| Node | results | results | Error % |
| 632a | 2457.56 | 2457.56 | 0 |
| 632b | 2497.59 | 2497.59 | 0 |
| 632c | 2441.93 | 2441.93 | 0 |
| 645a | 0 | 0 | |
| 645b | 2475.37 | 2475.36 | 4.04e−6 |
| 645c | 2437.41 | 2458.93 | 8.82e−3 |
| 646a | 0 | 0 | |
| 646b | 2471.22 | 2456.61 | 5.91e−3 |
| 646c | 2432.49 | 2455.10 | 9.29e−3 |

We consider the IEEE 37-bus distribution test feeder shown in FIG. 6. By applying the invented method for placing CPMUs on radial distribution networks, the locations of the IEEE 37-bus that need the placement of CPMUs are highlighted in the figure. A total of 15 CPMUs and 1 VPMU at the substation (i.e. bus 799) are needed. By applying the invented method for real-time state estimation for radial distribution networks, the state estimation results were compared with the benchmark results which were obtained by the power flow computation in Table 2. The very small error indicates the accuracy of the invented method on this small test system.

TABLE 2
The state estimation results were compared with the benchmark
results which were obtained by the power flow computation.

| | Power flow | State estimation | |
|---|---|---|---|
| Node | results | results | Error % |
| 720a | 2664.49 | 2664.49 | 0 |
| 720b | 2778.28 | 2778.28 | 0 |
| 720c | 2732.44 | 2732.44 | 0 |
| 706a | 2664.45 | 2664.55 | 3.75e−5 |
| 706b | 2777.4 | 2779.29 | 6.80e−4 |
| 706c | 2731.51 | 2731.91 | 1.46e−4 |
| 725a | 2664.43 | 2664.58 | 5.63e−5 |
| 725b | 2776.59 | 2780.13 | 1.27e−3 |
| 725c | 2730.84 | 2731.32 | 1.76e−4 |

We consider the IEEE 123-bus distribution test feeder shown in FIG. 14. By applying the invented method for placing CPMUs on radial distribution networks, the locations of the IEEE 123-bus that need the placement of CPMUs are highlighted in the figure. A total of 41 CPMUs and 1 VPMU at the substation (i.e. bus 150) are needed. By applying the invented method for real-time state estimation for radial distribution networks, the state estimation results were compared with the benchmark results which were obtained by the power flow computation in Table 3 for single-phase nodes and in Table 4 for three-phase nodes. The very small error indicates the accuracy of the invented method on this large test system.

TABLE 3
The state estimation results were compared with
the benchmark results which were obtained by the
power flow computation on Single-phase nodes.

| | Power flow | State estimation | |
|---|---|---|---|
| Node | results | results | Error % |
| 67a | 2487.56 | 2487.56 | 0 |
| 68a | 2483.88 | 2484.68 | 3.22E−04 |
| 69a | 2479.67 | 2481.41 | 7.02E−04 |
| 70a | 2476.68 | 2479.12 | 9.85E−04 |
| 71a | 2475.00 | 2477.82 | 1.14E−03 |

TABLE 4
The state estimation results were compared with the
benchmark results which were obtained by the
power flow computation on three-phase nodes.

| | Power flow | State estimation | |
|---|---|---|---|
| Node | results | results | Error % |
| 97a | 2485.15 | 2485.15 | 0 |
| 97b | 2475.39 | 2475.39 | 0 |
| 97c | 2483.23 | 2483.23 | 0 |
| 98a | 2484.66 | 2483.91 | 3.02E−04 |
| 98b | 2474.77 | 2473.83 | 3.80E−04 |
| 98c | 2482.73 | 2482.19 | 2.18E−04 |
| 99a | 2485.36 | 2483.53 | 7.36E−04 |
| 99b | 2472.8 | 2470.98 | 7.36E−04 |
| 99c | 2481.92 | 2479.59 | 9.39E−04 |
| 100a | 2485.83 | 2483.63 | 8.85E−04 |
| 100b | 2472.64 | 2470.60 | 8.25E−04 |
| 100c | 2480.95 | 2478.38 | 1.04E−03 |
| 450a | 2485.83 | 2483.66 | 8.73E−04 |
| 450b | 2472.64 | 2470.58 | 8.33E−04 |
| 450c | 2480.95 | 2478.31 | 1.06E−03 |

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method of placing phasor measurement units for distribution networks having a plurality of nodes, the network comprising: a main feeder line attached to a source at a source node and at least one node with a lateral branching from the node on the main feeder line, the method comprising the steps of:
a) placing a voltage phasor measurement unit and a current phasor measurement unit directly after the source node;
b) locating a next node downstream along the main feeder line and for the located next node downstream, determining a type of node located, a type of line between the source node and the located next node downstream and whether the located next node downstream is an end node of the main feeder line;
wherein if the located next node downstream is branching node, placing a current phasor measurement unit on all laterals between the branching node and an end of the lateral branching from the branching node;
repeating step b) until reach the end node of the main feeder line;
c) determining if any of the located next nodes downstream of the source node are attached to a dispersed generator and placing a current phasor measurement unit on the main feeder line connecting the next node and the dispersed generator
d) outputting placement locations of all phasor measurement units placed to a controller.

2. The method of claim 1, wherein if the distribution network is a weakly-meshed distribution network, prior to step (a) of placing a voltage phasor measurement unit and a current phasor measurement unit directly after the source node, identifying any loops of the weakly-meshed distribution network and for each identified loop, isolating a line of the loop between two nodes on the main feeder line and placing a CPMU at each of the two nodes on the isolated line.

3. The method of claim 2, wherein the line in the loop which is isolated is a line between the main feeder line and the lateral.

4. The method of claim 1, wherein the source is a substation.

5. The method of claim 1, wherein the line between the source node and the located next node downstream of the source node is a distribution line.

6. The method of claim 5, wherein the located next node downstream is k+1 and the voltage Vₖ₊₁ of the located next node downstream is equivalent to Vₖ−Zₖ*(Iₖ−0.5Yₖ*Vₖ) and the current I′ₖ₊₁ of the located next node downstream is equivalent to Zₖ⁻¹*(Vₖ₊₁−Vₖ)+0.5Yₖ₊₁*Vₖ₊₁.

7. The method of claim 1, wherein the line between the source node and the located next node downstream of the source node is a switch.

8. The method of claim 7, wherein the source node is k and the located next node downstream is k+1, and the voltage, Vₖ of the located next node downstream is Vₖ₊₁ and the current, I′ₖ of the located next node downstream is equivalent to −I′ₖ₊₁.

9. The method of claim 1, wherein the line between the source node and the located next node downstream of the source node is a transformer.

10. The method of claim 9, wherein the source node is k and of the located next node
downstream is k+1 and the transformer has an admittance matrix of
$$[ \begin{matrix}{Y}_{k}^{PP} & {Y}_{k}^{PS} \\ {Y}_{k}^{SP} & {Y}_{k}^{SS}\end{matrix} ] ,$$
and the voltage, Vₖ₊₁ is equivalent to (Yₖ^{SP})^{31 1}*(Iₖ−Yₖ^{PP}Vₖ) and the current, I′ₖ₊₁ is equivalent to (Yₖ^{SP})*Vₖ+Yₖ^{SS}Vₖ₊₁.

11. The method of claim 1, wherein the located next downstream node is a loop node.

12. The method of claim 1, wherein when the located next downstream node is a branching node, further comprising determining loads of the network further comprising the steps of:
for each lateral of the branching node, obtaining an actual injected power into the lateral by using a measure current phasor in the lateral multiplied by the computer voltage phasor at the branching node;
determining an initial power loss for each lateral and deducting the power losses from the actual power of the lateral;
for each node of the lateral, obtaining load types, average daily demands, and class-specific load estimate factor and reactive load demand estimate; and
for each lateral, obtaining a real load demand estimate of each node of the lateral.

13. A method of improving accuracy of pseudo-measurements made in, distribution networks having a plurality of nodes, the network comprising: a main feeder line attached to a source at a source node and at least one node with a lateral branching from the node on the main feeder line, the method comprising the steps of:
a) locating a next node downstream along the main feeder line and for the located next node downstream;
b) calculating load current in the located next node downstream;
c) storing the calculations of the loads measured;
d) when all loads have been measured, identifying a load point on the main feeder line that is after two-thirds of all of the loads measured;
e) placing a current phasor measurement unit and a voltage phasor measurement unit on the identified load point;
f) wherein for nodes located downstream of the two-thirds load point, performing state estimation comprising the steps of:
i) determining a type of node located, a type of line between the source node and the located next node downstream and whether the located next node downstream is an end node of the main feeder line;
ii) wherein if the located next node downstream is branching node, placing a current phasor measurement unit on all laterals between the branching node and an end of the lateral branching from the branching node;
repeating step (f)(ii) until reach the end node of the main feeder line;
iii) determining if any of the located next nodes downstream of the source node are attached to a dispersed generator and placing a current phasor measurement unit on the main feeder line connecting the next node and the dispersed generator;
iv) outputting placement locations of all phasor measurement units placed to a controller;
g) for nodes between the source node and the identified two-thirds load point, deriving an equivalent circuit.

14. The method of claim 13, wherein deriving an equivalent circuit further comprises the steps of:
solving V₁,V₂,V₃, . . . V_{(2/3)}
solving for each load by α
applying V₁(α),V₂(α),V₃(α), . . . V_{(2/3)}(α)
solving minimum
$$α \{ {\vert {V}_{( \frac{2}{3} )} ( α ) - {V}_{( \frac{2}{3} )}^{meas} \vert}^{2} + W {\vert {I}_{( \frac{2}{3} )} ( α ) - {I}_{( \frac{2}{3} )}^{meas} \vert}^{2} \}$$
with W as α*; and
using α* as the scaling factor Vᵢ(α*) and scaling the pseudo-measurement load by the scaling factor.
